(19) United States
(12) Patent Application Publication
(10) Pub. No.: US 2009/0242010 A1
(43) Pub. Date: Oct. 1, 2009

(54) Method to Form a Photovoltaic Cell Comprising a Thin Lamina Bonded to a Discrete Receiver Element

(75) Inventor: S. Brad Herner, San Jose, CA (US)

Correspondence Address: THE MUELLER LAW OFFICE, P.C., 12951 Harwick Lane, San Diego, CA, 92130, US

(73) Assignee: Twin Creeks Technologies, Inc., Santa Clara, CA (US)

(21) Appl. No.: 12/057,265

(22) Filed: Mar. 27, 2008

(51) Int. Cl. H01L 31/028; H01L 31/042; H01L 31/04; B32B 38/04; B32B 38/00

(52) U.S. Cl. 136/244; 136/252; 136/261; 156/254; 156/64

(57) ABSTRACT

A donor semiconductor wafer is processed to define a cleave plane, then affixed to a discrete receiver element, which may be glass, metal or a metal compound, plastic, or semiconductor. A semiconductor lamina is cleaved from the donor wafer at the cleave plane. A photovoltaic assembly is fabricated comprising the semiconductor lamina and the receiver element. The photovoltaic assembly comprises a photovoltaic cell. After fabrication, the photovoltaic assembly can be inspected for defects and tested for performance, and select photovoltaic assemblies can be assembled into a completed photovoltaic module.

### RELATED APPLICATIONS

This application is related to Herner et al., U.S. patent application Ser. No. ______, “A Photovoltaic Assembly Including a Conductive Layer Between a Semiconductor Lamina and a Receiver Element,” (attorney docket number TCA-003) filed on even date herewith and hereby incorporated by reference.

### BACKGROUND OF THE INVENTION

The invention relates to a method to form a photovoltaic assembly comprising a thin semiconductor lamina bonded to a receiver element.

Photovoltaic cells are most often formed of silicon. The volume of silicon in the photovoltaic cell is often the largest cost item of the cell; thus methods to reduce consumption of silicon will serve to reduce cost.

Photovoltaic cells are generally fabricated, tested, and sorted according to performance. Many cells are electrically connected in series on a photovoltaic module, such that the cell having the poorest performance limits the performance of the entire module. Thus it is preferable for cells having similar performance to be grouped together in a photovoltaic module.

A method to reduce the amount of silicon used in fabrication of photovoltaic cells, while also allowing photovoltaic cells to be tested, sorted, and selected for inclusion in a photovoltaic module, would be advantageous.

### SUMMARY OF THE PREFERRED EMBODIMENTS

The present invention is defined by the following claims, and nothing in this section should be taken as a limitation on those claims. In general, the invention is directed to a method to form a photovoltaic assembly including a thin semiconductor lamina. A plurality of such photovoltaic assemblies can be attached to a substrate or superstrate to form a photovoltaic module.

A first aspect of the invention provides for a method for forming a photovoltaic assembly, the method comprising: affixing a semiconductor donor body at a first surface to a receiver element, the semiconductor donor body having a donor widest dimension and the receiver element having a receiver widest dimension, wherein the receiver widest dimension does not exceed the donor widest dimension by more than 50 percent; cleaving a semiconductor lamina from the semiconductor donor body along a cleave plane, wherein the semiconductor lamina remains affixed to the receiver element; and completing fabrication of the photovoltaic assembly, wherein the completed photovoltaic assembly comprises the semiconductor lamina and the receiver element, and wherein the semiconductor lamina comprises a portion of a base or emitter of a photovoltaic cell.

An embodiment of the invention provides for a method for forming a photovoltaic module, the method comprising: forming a plurality of photovoltaic assemblies, each photovoltaic assembly comprising a semiconductor lamina and a receiver element, wherein each semiconductor lamina has a thickness between about 0.2 and about 50 microns, each semiconductor lamina is bonded to one of the receiver elements, each receiver element has a thickness of at least 80 microns, and each semiconductor lamina comprises at least a portion of a base or emitter of a photovoltaic cell; testing each photovoltaic assembly of the plurality; selecting a subset of the plurality for inclusion in the photovoltaic module based on results of the testing step; and affixing at least some of the plurality of photovoltaic assemblies to a substrate or superstrate to form the photovoltaic module.

Another aspect of the invention provides for a photovoltaic assembly comprising: a semiconductor lamina, the semiconductor lamina having a thickness between about 1 and about 50 microns and having a lamina widest dimension; and a receiver element having a receiver widest dimension, wherein the receiver widest dimension does not exceed the lamina widest dimension by more than about 50 percent, wherein the receiver is bonded to the semiconductor lamina.

Still another aspect of the invention provides for a first photovoltaic assembly comprising: a first photovoltaic cell; a semiconductor lamina having a thickness between about 1 and about 20 microns, the semiconductor lamina comprising at least a portion of a base of the first photovoltaic cell, the semiconductor lamina having a lamina widest dimension; and a receiver element having a receiver widest dimension, wherein the receiver widest dimension does not exceed the lamina widest dimension by more than about 50 percent, wherein the receiver is bonded to the semiconductor lamina.

Another embodiment of the invention provides for a photovoltaic module comprising: i) a plurality of photovoltaic assemblies, each photovoltaic assembly comprising: a) a semiconductor lamina having a thickness between about 0.2 and about 50 microns, the semiconductor lamina comprising at least the base of a photovoltaic cell, b) a receiver element at least about 80 microns thick, the semiconductor lamina bonded to the receiver element, and c) the photovoltaic cell; and ii) a substrate or superstrate, each of the photovoltaic assemblies affixed to the substrate or superstrate, wherein the photovoltaic cell of one photovoltaic assembly is electrically connected in series to the photovoltaic cell of at least one other photovoltaic assembly.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view depicting a prior art photovoltaic cell.

FIGS. 2a-2d are cross-sectional views showing stages in formation of an embodiment of Sivaram et al., U.S. patent application Ser. No. 12/026,530.

FIG. 3 is a plan view showing a photovoltaic module formed according to an embodiment of Sivaram et al.

FIGS. 4a-4d are cross-sectional views showing stages in formation of an embodiment of the present invention.

FIGS. 5a-5c are cross-sectional views showing stages in formation of another embodiment of the present invention.

FIGS. 6a and 6b are cross-sectional views showing stages in formation of an embodiment of the present invention.

FIGS. 7a and 7b are cross-sectional views showing stages in formation of still another embodiment of the present invention.

FIGS. 8a and 8b are cross-sectional views showing stages in formation of still another embodiment of the present invention, in which a photovoltaic assembly is affixed to a superstrate.

### DETAILED DESCRIPTION OF THE PREFERRED EMBODIMENTS

A conventional photovoltaic cell is formed in a substantially crystalline silicon wafer, which may be monocrystalline, multicrystalline, polycrystalline, or microcrystalline. The photovoltaic cell is affixed to a substrate or superstrate, connected electrically in series with other photovoltaic cells, forming a photovoltaic module.

A conventional prior art photovoltaic cell includes a p-n diode; an example is shown in FIG. 1. A depletion zone forms at the p-n junction, creating an electric field. Incident photons will knock electrons from the conduction band to the valence band, creating electron-hole pairs. Within the electric field at the p-n junction, electrons tend to migrate toward the n region of the diode, while holes migrate toward the p region, resulting in current. This current can be called the photocurrent. Typically the dopant concentration of one region will be higher than that of the other, so the junction is either a p+/n− junction (as shown in FIG. 1) or a p−/n+ junction. The more lightly doped region is known as the base of the photovoltaic cell, while the more heavily doped region is known as the emitter. Most carriers are generated within the base, and it is typically the thickest portion of the cell. The base and emitter together form the active region of the cell.

A silicon wafer is typically about 200 to 300 microns thick. Silicon photovoltaic cells need not be this thick to be effective or commercially useful. A large portion of the cost of conventional photovoltaic cells is the cost of silicon feedstock, so decreasing the thickness of a photovoltaic cell may reduce cost. It is known to slice silicon wafers as thin as about 180 microns, but such wafers are fragile and prone to breakage. Methods to form a variety of thin photovoltaic cells, having a thickness of 100 microns or less, for example between about 1 and about 50 microns, in some embodiments between about 2 and about 20 microns, are disclosed in Sivaram et al., U.S. patent application Ser. No. 12/026,530, “Method to Form a Photovoltaic Cell Comprising a Thin Lamina,” filed Feb. 5, 2008, hereby incorporated by reference.

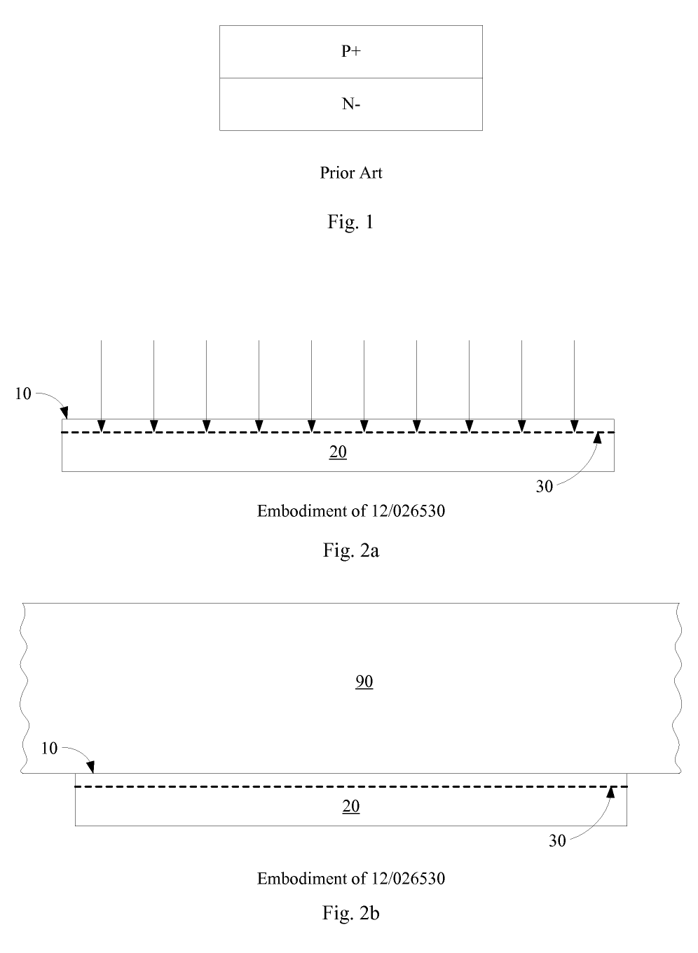

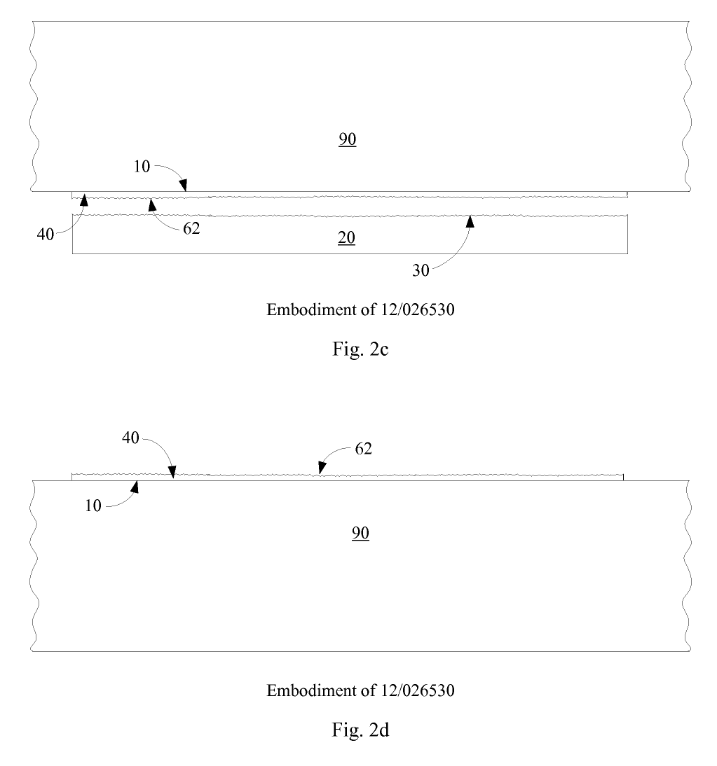

Referring to FIG. 2a, in embodiments of Sivaram et al., a semiconductor donor wafer 20 is implanted with one or more species of gas ions, for example hydrogen or helium ions. The implanted ions define a cleave plane 30 within the semiconductor donor wafer. As shown in FIG. 2b, donor wafer 20 is affixed at first surface 10 to receiver 90. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 50 microns thick, in some embodiments between about 1 and about 10 microns thick. FIG. 2d shows the structure inverted, with substrate 90 at the bottom, as during operation.

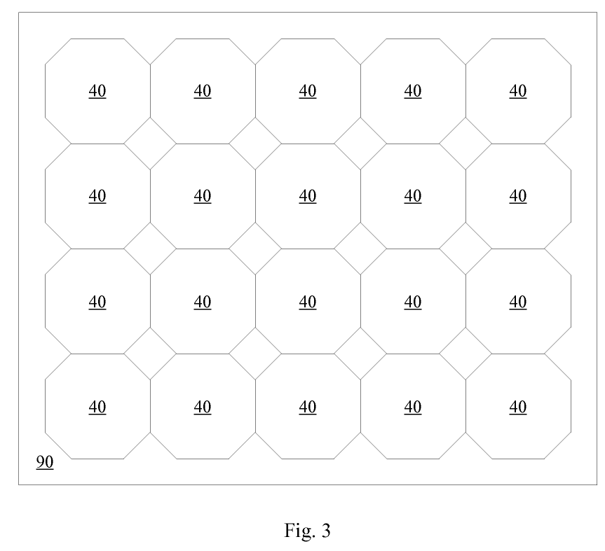

In embodiments of Sivaram et al., a plurality of donor wafers 20 can be affixed to a single substrate 90, as shown in FIG. 3, or to a superstrate. Next a plurality of laminae 40 are formed, each cleaved from one of donor wafers 20, and additional processing performed on all laminae 40 while affixed to substrate 90 to complete the cells, forming the completed photovoltaic module shown in FIG. 3.

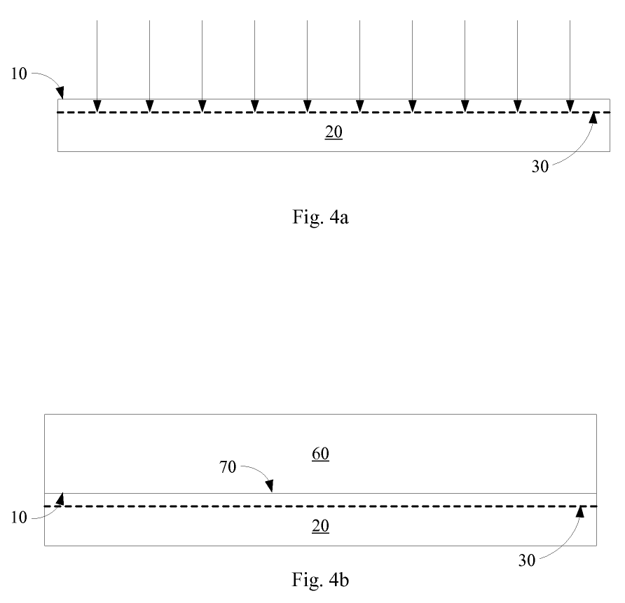

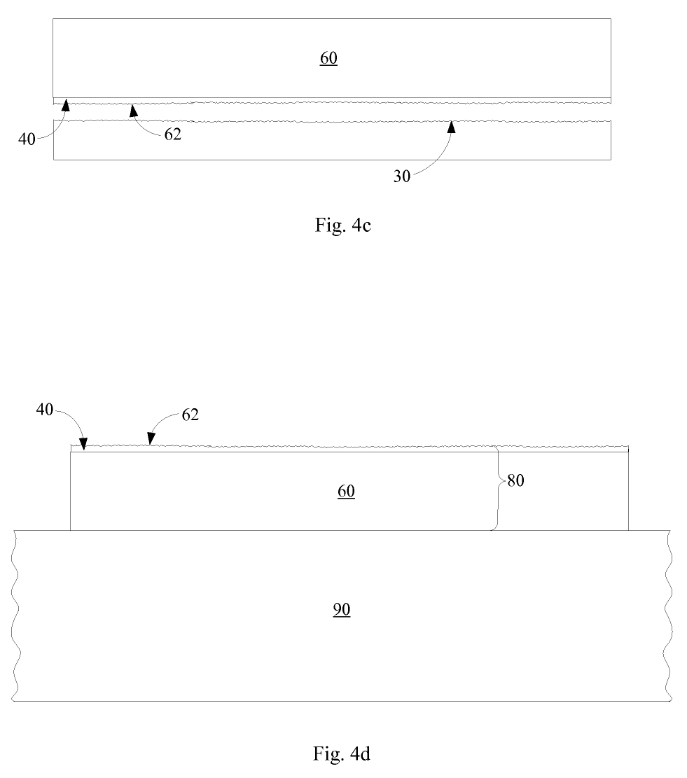

Processing many laminae while they are affixed to a module substrate or superstrate may not always be desirable, however. Referring to FIG. 4a, in the present invention, first surface 10 of semiconductor donor wafer 20 is subjected to processing, such as texturing, doping, deposition of one or more layers (not shown), etc., and then is implanted with one or more species of gas ions to define cleave plane 30. Next, turning to FIG. 4b, first surface 20 of donor wafer 10 is affixed to receiving surface 70 of receiver element 60. Receiver element 60 is not the final substrate or superstrate which will eventually support a plurality of series-connected photovoltaic cells arrayed side-by-side in a photovoltaic module. Receiving surface 70 of receiver element 60 is smaller in area than the substrate or superstrate of the photovoltaic module. For example, donor wafer 20 and receiver element 60 may be any standard wafer size, such as 100, 125, 150, 200, or 300 mm, while the module substrate or superstrate may be large enough to accommodate 12, 36, or more of these wafers arrayed side-by-side. Receiver element 60 may be a standard wafer size, and may also be called a receiver wafer. First surface 10 of donor wafer 20 may be any shape, for example circular, square, or octagonal. In most embodiments, receiving surface 70 of receiver wafer 60 is substantially the same size and shape as first surface 10 of donor wafer 20, though it may be different. It may be preferred for receiving surface 70 of receiver wafer 60 to be slightly larger than first surface 10 of donor wafer 20. Receiver wafer 60 may be formed of any practical material, such as glass, metal or metal compound, plastic, or semiconductor, or may be a stack comprising different materials. Processing may have been performed to either or both surfaces of receiver wafer 60 before donor wafer 20 is affixed to it, or after.

As shown in FIG. 4c, lamina 40 is cleaved from donor wafer 20 at cleave plane 30, where lamina 40 remains affixed to receiver wafer 60. Further processing is performed to complete fabrication of a photovoltaic cell that comprises lamina 40. Referring to FIG. 4d, a photovoltaic assembly 80 has been fabricated, where photovoltaic assembly 80 comprises semiconductor lamina 40 and receiver wafer 60. Photovoltaic assembly 80 includes a photovoltaic cell; as will be described, in some embodiments semiconductor lamina 40 may comprise at least a portion of a base or emitter of a photovoltaic cell, while in others lamina 40 comprises the entire photovoltaic cell. FIG. 4d shows photovoltaic assembly 80 inverted, with receiver element 60 at the bottom. In FIG. 4d, photovoltaic assembly 80 is affixed to a panel-sized module substrate 90.

Summarizing, aspects of the present invention provide for a method for forming a photovoltaic assembly, the method comprising: affixing a semiconductor donor body at a first surface to a receiver element, the semiconductor donor body having a donor widest dimension and the receiver element having a receiver widest dimension, wherein the receiver widest dimension does not exceed the donor widest dimension by more than 50 percent; cleaving a semiconductor lamina from the semiconductor donor body along a cleave plane, wherein the semiconductor lamina remains affixed to the receiver element; and completing fabrication of the photovoltaic assembly, wherein the completed photovoltaic assembly comprises the semiconductor lamina and the receiver element, and wherein the semiconductor lamina comprises a portion of a base or emitter of a photovoltaic cell.

The completed photovoltaic assembly comprises a semiconductor lamina, the semiconductor lamina having a thickness which may be between about 1 and about 50 microns and having a lamina widest dimension; and a receiver element having a receiver widest dimension, wherein the receiver widest dimension does not exceed the lamina widest dimension by more than about 50 percent, wherein the receiver is bonded to the semiconductor lamina.

A plurality of photovoltaic assemblies can be formed as described. Because the photovoltaic assemblies are discrete, wafer-sized units, not yet affixed to a substrate or superstrate, each can then be individually inspected for defects and tested for conversion efficiency. Specific photovoltaic assemblies, a subset of the total, can be selected from among the plurality for inclusion in a photovoltaic module. Multiple photovoltaic cells are generally connected electrically in series, in which case the current delivered by the photovoltaic module is limited by the performance of the weakest photovoltaic cell in the series. Thus, after testing and sorting, cells with similar conversion efficiencies can be grouped together for inclusion in a photovoltaic module.

In the completed photovoltaic module, then, a plurality of photovoltaic assemblies are affixed to a superstrate or substrate. Each photovoltaic assembly includes a photovoltaic cell. The photovoltaic cell of at least one photovoltaic assembly is connected electrically in series with the photovoltaic cell of at least one other photovoltaic assembly.

As will be described, in most embodiments, after affixing of donor wafer 20 to receiver element 60 and cleaving of lamina 40 from donor wafer 20, there is additional processing to be performed in order to complete fabrication of the photovoltaic cell, including texturing, deposition, doping, etc. If the lamina is formed affixed to the substrate or superstrate of the photovoltaic module, as in embodiments of Sivaram et al., these steps must be performed on the entire module, which may require custom tools. If the lamina is bonded to a discrete receiver element which is about the size of a conventional wafer, as in embodiments of the present invention, these steps can be performed using conventional tools, simplifying processing and reducing cost.

### Discussion: Implant and Exfoliation

An effective way to cleave a thin lamina from a semiconductor donor body is by implanting gas ions into the semiconductor donor body to define a cleave plane, then to exfoliate the lamina along the cleave plane. Referring to FIG. 4a, one or more species of ions is implanted (indicated by arrows) through first surface 10 of wafer 20. A variety of gas ions may be used, including hydrogen and helium, singly or in combination. Each implanted ion will travel some depth below first surface 10. It will be slowed by electronic interactions and nuclear collisions with atoms as it travels through the lattice. The nuclear collisions may lead to displacement of the lattice atoms creating vacant lattice sites.

After implant, there will be a distribution both of ion depths and of lattice damage; there will be a maximum concentration in each distribution. If hydrogen is implanted, the maximum concentration of damage will generally be the cleave plane. If the implant includes helium, or some other gas ion, but does not include hydrogen, the maximum concentration of implanted ions will be the cleave plane. In either case, the ion implantation step defines the cleave plane, and implant energy defines the depth of the cleave plane. It is preferred that the hydrogen implant is performed before the helium implant.

The depth of the implanted ions is determined by the energy at which the gas ions are implanted. At higher implant energies, ions travel farther, increasing the depth of the cleave plane. The depth of the cleave plane in turn determines the thickness of the lamina.

Preferred thicknesses for the lamina are between about 0.2 and about 100 microns; thus preferred implant energies for H+ range from between about 20 keV and about 10 MeV. Preferred implant energies for He+ ions to achieve these depths also range between about 20 keV and about 10 MeV.

As described by Agarwal et al. in “Efficient production of silicon-on-insulator films by co-implantation of He+ with H+”, American Institute of Physics, vol. 72, num. 9, pp. 1086-1088, March 1998, hereby incorporated by reference, it has been found that by implanting both H+ and He+ ions, the required dose for each can be significantly reduced. Decreasing dose decreases time and energy spent on implant, and may significantly reduce processing cost.

To form a lamina having a thickness of about 1 micron, implant energy for hydrogen should be about 100 keV; for a lamina of about 2 microns, about 200 keV, for a lamina of about 5 microns, about 500 keV, and for a lamina of about 10 microns, about 1000 keV. If hydrogen alone is implanted, the dose for a lamina of about 1 or about 2 microns will range between about 0.4×10¹⁷ and about 1.0×10¹⁷ ions/cm², while the dose for a lamina of about 5 or about 10 microns will range between about 0.4×10¹⁷ and about 2.0×10¹⁷ ions/cm².

If hydrogen and helium are implanted together, the dose for each is reduced compared to when either is implanted separately. When implanted with helium, hydrogen dose to form a lamina of about 1 or about 2 microns will be between about 0.1×10¹⁷ and about 0.3×10¹⁷ ions/cm², while to form a lamina of about 5 or about 10 microns hydrogen dose may be between about 0.1×10¹⁷ and about 0.5×10¹⁷ ions/cm².

When hydrogen and helium are implanted together, to form a lamina having a thickness of about 1 micron, implant energy for helium should be about 50 to about 200 keV; for a lamina of about 2 microns, about 100 to about 400 keV; for a lamina of about 5 microns, about 250 to about 1000 keV; and for a lamina of about 10 microns, about 500 keV to about 1000 keV. When implanted with hydrogen, helium dose to form a lamina of about 1 or about 2 microns may be about 0.1×10¹⁷ to about 0.3×10¹⁷ ions/cm², while to form a lamina of about 5 or about 10 microns, helium dose may be between about 0.1×10¹⁷ and about 0.5×10¹⁷ ions/cm². It will be understood that these are examples. Energies and doses may vary, and intermediate energies may be selected to form laminae of intermediate, lesser, or greater thicknesses.

Once ion implantation has been completed, further processing may be performed on wafer 20. Elevated temperature will induce exfoliation at cleave plane 30; thus until exfoliation is intended to take place, care should be taken, for example by limiting temperature and duration of thermal steps, to avoid inducing exfoliation prematurely. Once processing to first surface 10 has been completed, as shown in FIG. 4b, wafer 20 can be affixed to receiver wafer 60.

Turning to FIG. 4c, to induce exfoliation, receiver wafer 60 with affixed wafer 20 is subjected to elevated temperature, for example between about 200 and about 800 degrees C. Exfoliation proceeds more quickly at higher temperature. In some embodiments, the temperature step to induce exfoliation is performed at between about 200 and about 500 degrees C., with anneal time on the order of hours at 200 degrees C., and on the order of seconds at 500 degrees C. As temperature increases, bubbles or defects at the cleave plane begin to expand as the implanted gas atoms diffuse in all directions, forming micro-cracks. Eventually the micro-cracks merge and the pressure exerted by the expanding gas causes lamina 40 to separate entirely from the donor silicon wafer 20 along cleave plane 30. The presence of receiver wafer 60 forces the micro-cracks to expand sideways, forming a continuous split along cleave plane 30, rather than expanding perpendicularly to cleave plane 30 prematurely, which would lead to blistering and flaking at first surface 10.

FIG. 4d shows the structure inverted, with receiver wafer 60 on the bottom. First surface 10 of lamina 40 remains affixed to receiver wafer 60, and receiver wafer 60 is affixed to substrate 90.

For clarity, several examples of fabrication of a photovoltaic assembly comprising a semiconductor lamina and a receiver wafer, where the photovoltaic assembly can then be tested, sorted, selected, and affixed, with other photovoltaic assemblies, to form a photovoltaic module, will be provided. For completeness, many materials, conditions, and steps will be described. It will be understood, however, that many of these details can be modified, augmented, or omitted while the results fall within the scope of the invention.

### Example

### Standard Front-and-Back Contact Cell

The process begins with a donor body of an appropriate semiconductor material. An appropriate donor body may be a monocrystalline silicon wafer of any practical thickness, for example from about 300 to about 1000 microns thick. In alternative embodiments, the wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having crystals that are on the order of a millimeter in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline.

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with no unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

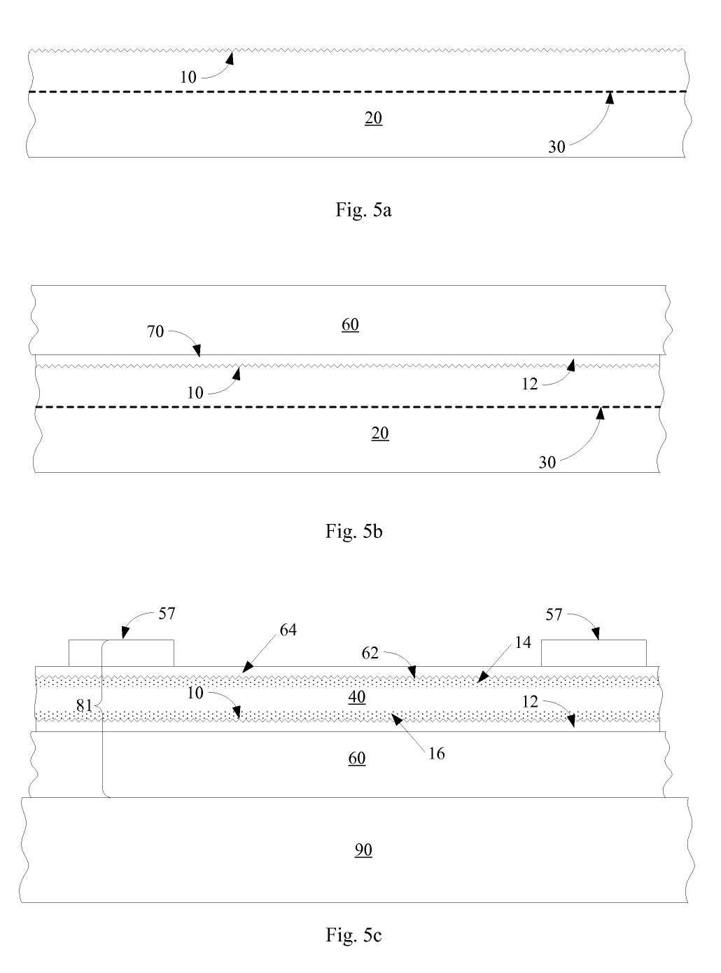

Referring to FIG. 5a, wafer 20 is formed of monocrystalline silicon which is preferably lightly doped to a first conductivity type. The present example will describe a relatively lightly p-doped wafer 20 but it will be understood that in this and other embodiments the dopant types can be reversed. Dopant concentration may be between about 1×10¹⁴ and 1×10¹⁸ atoms/cm³; for example between about 3×10¹⁴ and 1×10¹⁵ atoms/cm³; for example about 5×10¹⁴ atoms/cm³. Desirable resistivity for p-type silicon may be, for example, between about 133 and about 0.04 ohm-cm, preferably about 44 to about 13.5 ohm-cm, for example about 27 ohm-cm. For n-type silicon, desirable resistivity may be between about 44 and about 0.02 ohm-cm, preferably between about 15 and about 4.6 ohm-cm, for example about 9 ohm-cm.

First surface 10 is optionally treated to produce surface roughness, for example, to produce a Lambertian surface. The ultimate thickness of the lamina limits the achievable roughness. In conventional silicon wafers for photovoltaic cells, surface roughness, measured peak-to-valley, is on the order of one micron. In embodiments of the present invention, the thickness of the lamina may be between about 0.2 and about 100 microns. Preferred thicknesses include between about 1 and about 80 microns; for example, between about 1 and about 20 microns or between about 2 and about 20 microns. Practically, any thickness in the range between about 0.2 and about 100 microns is achieveable; advantageous thicknesses may be between about 1 and about 1.5, 2, 3, 5, 8, 10, 20, or 50 microns.

If the final thickness is about 2 microns, clearly surface roughness cannot be on the order of microns. For all thicknesses, a lower limit of surface roughness would be about 500 angstroms. An upper limit would be about a quarter of the film thickness. For a lamina 1 micron thick, surface roughness may be between about 600 angstroms and about 2500 angstroms. For a lamina having a thickness of about 10 microns, surface roughness will be less than about 25000 angstroms, for example between about 600 angstroms and 25000 angstroms. For a lamina having a thickness of about 20 microns, surface roughness may be between about 600 angstroms and 50000 angstroms.

This surface roughness can be produced in a variety of ways which are well-known in the art. For example, a wet etch such as a KOH etch selectively attacks certain planes of the silicon crystal faster than others, producing a series of pyramids on a (100) oriented wafer, where the (111) planes are preferentially etched faster. A non-isotropic dry etch may be used to produce texture as well. Any other known methods may be used. The resulting texture is depicted in FIG. 5a. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001.

In some embodiments, diffusion doping may be performed at first surface 10. First surface 10 will be more heavily doped in the same conductivity type as original wafer 20, in this instance p-doped. Doping may be performed with any conventional p-type donor gas, for example B₂H₆ or BCl₃. In other embodiments, this diffusion doping step can be omitted.

Next ions, preferably hydrogen or a combination of hydrogen and helium, are implanted to define a cleave plane 30. Note that the plane of maximum distribution of implanted ions, and of implant damage, is conformal. Any irregularities at first surface 10 will be reproduced in cleave plane 30. Thus in some embodiments it may be preferred to texture surface 10 after the implant step rather than before.

After implant, first surface 10 is cleaned. Once the implant has been performed, exfoliation will occur once certain conditions, for example elevated temperature, are encountered. It is necessary, then, to keep processing temperature and duration below those which will initiate exfoliation until exfoliation is intended to take place.

Referring to FIG. 5b, donor wafer 20 is affixed to a receiver element, which may be wafer-sized and will be called receiver wafer 60, at first surface 10. Receiver wafer 60 may be any appropriate material, such as semiconductor, glass, metal or metal compound, or high-temperature plastic. Receiver wafer 60 preferably is formed of a material that can tolerate relatively high temperature. For example, receiver wafer 60 may be borosilicate glass. In some embodiments, receiver wafer 60 may be float glass, and may be between about 200 and about 800 microns thick, for example between about 200 and about 400 microns thick.

A reflective, conductive, metallic material, for example titanium or aluminum, or alloys or silicides thereof, preferably contacts first surface 10. Other alternatives for this conductive layer, in this and other embodiments, include chromium, molybdenum, tantalum, zirconium, vanadium, tungsten, nickel, copper, ruthenium, niobium, cobalt, zinc, indium, antimony, tin, lead, or iron, or any combination or alloy of any of these materials. This conductive layer can be any metal, metal compound, metal alloy, or metal silicide, or a combination of any of these. In some embodiments, it may be preferred to deposit a thin layer 12 of aluminum onto first surface 10. For example, aluminum can be sputter deposited onto first surface 10. In some embodiments, layer 12 may be between about 30 angstroms and about 2000 angstroms thick, for example about 150 angstroms thick. Alternatively, receiving surface 70 of receiver wafer 60 may be coated with aluminum or some other reflective metallic material. In other embodiments, an aluminum layer can be formed on both first surface 10 and on receiving surface 70 of receiver wafer 60.

In alternative embodiments, receiver wafer 60 can be a metal or metal alloy, such as titanium or aluminum. Pure aluminum has a relatively low melting temperature, so an aluminum alloy may be preferred, which may be coated with a thin layer of aluminum or titanium contacting donor wafer 20. Receiver wafer 60 may be formed of a relatively inexpensive and robust material, such as stainless steel, which may be coated with a reflective material which will contact first surface 10 of donor wafer 20. In this case, this reflective material also serves as a barrier between lamina 40 and the material of receiver wafer 60. If receiver wafer 60 is a metal or metal compound, its thickness will generally be at least 80 microns, for example between about 80 and about 500 microns, in some embodiments between about 100 and about 400 microns.

Donor wafer 20 can be any shape; common shapes are circular, square, and octagonal. It may be preferred for receiver element 60 to be substantially the same size and shape as donor wafer 20. Donor wafer 20 can be any size, though standard wafer sizes may be preferred, as standard equipment exists for handling them. Common wafer sizes are 100, 125, 150, 200, or 300 millimeters. In many embodiments, receiving surface 70 of receiver wafer 60 is slightly larger than first surface 10 of donor wafer 20, for example overlapping it on all sides by some millimeters. In most preferred embodiments, however, the widest dimension of receiver wafer 60 will not exceed the widest dimension of donor wafer 20 by more than 50 percent; in other embodiments, the widest dimension of receiver wafer 60 will not exceed the widest dimension of donor wafer 20 by more than about 10 percent or about 20 percent. In other embodiments, receiver wafer 60 may have a different shape than donor wafer 20. For example, receiver wafer 60 may be square, while donor wafer is an octagon that fits within the area of the square.

Donor wafer 20 and receiver wafer 60 may be bonded using known wafer bonding techniques, such as thermo compression bonding or low-temperature plasma bonding. As described in Herner et al. filed on even date herewith, thin metal layer 12 may tend to serve as an excellent adhesion layer between wafer 20 and receiver wafer 60, and bonding may be achieved with minimal pressure and/or temperature.

Turning to FIG. 5c, lamina 40 can now be cleaved from donor wafer 20 at cleave plane 30 as described earlier. Second surface 62 has been created by exfoliation. In FIG. 5c, the structure is shown inverted, with receiver wafer 60 on the bottom. As has been described, some surface roughness is desirable to increase light trapping within lamina 40 and improve conversion efficiency of the photovoltaic cell. The exfoliation process itself creates some surface roughness at second surface 62. In some embodiments, this roughness may alone be sufficient. In other embodiments, surface roughness of second surface 62 may be modified or increased by some other known process, such as a wet or dry etch, as may have been used to roughen first surface 10. If metal 12 is a p-type acceptor such as aluminum, annealing to the Al—Si eutectic temperature at this point or later will serve to form or additionally dope p-doped region 16.

Next a region 14 at the top of lamina 40 is doped through second surface 62 to a conductivity type opposite the conductivity type of the original wafer 20. In this example, original wafer 20 was lightly p-doped, so doped region 14 will be n-type. This doping may be performed by any conventional means. In preferred embodiments this doping step is performed by diffusion doping using any appropriate donor gas that will provide an n-type dopant, for example POCl₃.

Diffusion doping is typically performed at relatively high temperature, for example between about 700 and about 1000 degrees C., although lower temperature methods, such as plasma enhanced diffusion doping, can be performed instead. This elevated temperature will cause some aluminum from aluminum layer 12 to diffuse in at first surface 10 and become a p-type acceptor. This elevated temperature can serve as the anneal mentioned earlier to form a more heavily doped p-type region 16 which will serve to form a good electrical contact to aluminum layer 12. If doping of p-region 16 from aluminum layer 12 is sufficient, the earlier diffusion doping step performed at first surface 10 to form this region can be omitted. If oxygen is present during the n-type diffusion doping step, a thin layer of oxide (not shown) will form at second surface 62.

Edge-trimming may be performed by any conventional method, in this and other embodiments, to remove any electrical connection formed between n-doped region 14 and p-doped region 16 during this doping step.

Antireflective layer 64 is preferably formed, for example by deposition or growth, on second surface 62. Incident light enters lamina 40 through second surface 62; thus this layer should be transparent. In some embodiments antireflective layer 64 is silicon nitride, which has a refractive index of about 1.5 to 3.0; its thickness would be, for example, between about 500 and 2000 angstroms, for example about 650 angstroms.

Next wiring 57 is formed on layer 64. In some embodiments, this wiring is formed by screen printing conductive paste in the pattern of wiring, which is then fired at high temperature, for example between about 700 and about 900 degrees C. For example, if layer 64 is silicon nitride, it is known to screen print wiring using screen print paste containing silver. During firing, some of the silver diffuses through the silicon nitride, effectively forming a via through the insulating silicon nitride 64, making electrical contact to n-doped silicon region 14. Contact can be made to the silver remaining above antireflective layer 64. A completed photovoltaic assembly 81 is shown in FIG. 5c.

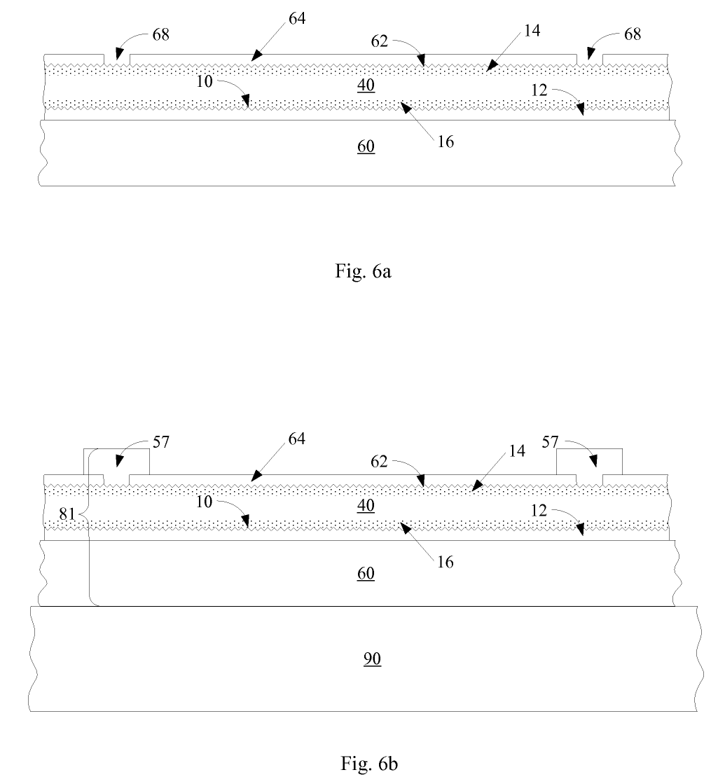

In an alternative embodiment, shown in FIG. 6a, instead of forming silver screen print wiring 57 on intact silicon nitride layer 64, a series of parallel trenches 68 are formed in silicon nitride layer 64, exposing the silicon of second surface 62 in each trench 68. Trenches 68 can be formed by any appropriate method, for example by photolithographic masking and etching. Optionally, a second diffusion doping step with an n-type dopant can be performed at this point, more heavily doping silicon exposed in trenches 68.

FIG. 6b shows wiring 57, which is formed contacting n-doped region 14 exposed in the trenches. Wiring 57 can be formed by any conventional means. It may be preferred to form a metal layer on silicon nitride layer 64, then form wiring 57 from the metal layer by photolithographic masking and etching. In an alternate embodiment, wiring 57 is formed by screen printing, for example to form aluminum wiring. Aluminum screen print paste can be fired at a lower temperature than the temperature required to diffuse silver from the silver paste through silicon nitride. Reducing processing temperature may be advantageous.

FIGS. 5c and 6b both show completed photovoltaic assembly 81 according to two embodiment of the present invention. In each, photovoltaic assembly 81 comprises lamina 40 and receiver wafer or element 60, and comprises a photovoltaic cell. Note that the lightly p-doped body of lamina 40 is the base of this cell, while heavily doped n-region 14 is the emitter; thus lamina 40 comprises a photovoltaic cell. Current is generated within lamina 40 when it is exposed to light. Electrical contact is made to both first surface 10 and second surface 62 of this cell. A conductive layer, aluminum layer 12, intervenes between semiconductor lamina 40 and receiver element 60.

A plurality of photovoltaic assemblies 81 is fabricated. Each is inspected for flaws, and the assemblies are tested, and may be sorted by performance. Photovoltaic assemblies are then selected from the plurality based on results of the testing step, assembled onto a substrate 90, and electrically connected to form a completed photovoltaic module. In alternative embodiments, photovoltaic assemblies 81 could be affixed to a transparent superstrate (not shown).

### Example

### Amorphous Emitter and Base Contacts

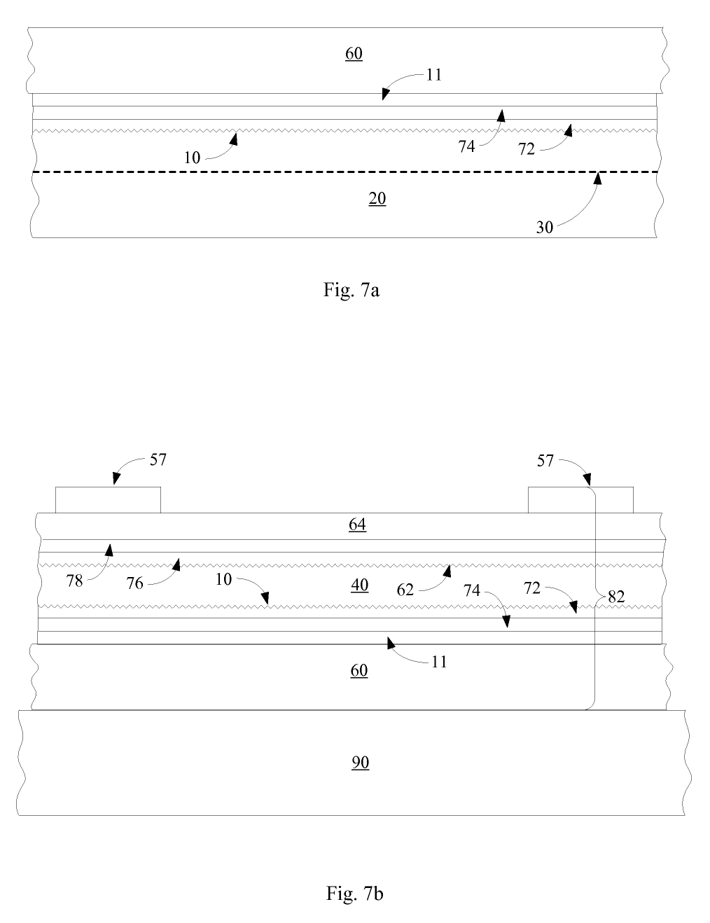

In another embodiment, one or both heavily doped regions of the cell are formed in amorphous semiconductor layers. Turning to FIG. 7a, to form this cell, in one embodiment, donor body 20 is a lightly n-doped silicon wafer (as always, in alternate embodiments, conductivity types can be reversed.) First surface 10 of wafer 20 is optionally roughened as in prior embodiments. After cleaning first surface 10, a layer 72 of intrinsic (undoped) amorphous silicon is deposited on first surface 10, followed by a layer 74 of n-doped amorphous silicon by any suitable method, for example by plasma enhanced chemical vapor deposition (PECVD). The combined thickness of amorphous layers 72 and 74 may be between about 200 and about 500 angstroms, for example about 350 angstroms. In one embodiment, intrinsic layer 72 is about 50 angstroms thick, while n-type amorphous layer 74 is about 300 angstroms thick. Gas ions are implanted through layers 74, 72 and into first surface 10 to define cleave plane 30 as in prior embodiments. It will be understood that the implant energy must be adjusted to compensate for the added thickness of amorphous layers 74 and 72.

A reflective, conductive metal 11 is formed on n-doped layer 74, on receiver element 60, or both, as in prior embodiments, and donor wafer 20 is affixed to receiver element 60 at first surface 10, with intrinsic layer 72, n-doped layer 74, and metal layer 11 intervening between them. Metal layer 11 can be aluminum, titanium, or any other suitable material. Receiver element 60 may be about the size of a conventional silicon wafer, and may be called a receiver wafer. Receiver wafer 60 can be any suitable material, for example borosilicate glass, stainless steel, titanium, aluminum or aluminum alloy, etc., which may or may not be coated, for example with aluminum or titanium. Donor wafer 20 and receiver wafer 60 are bonded using known wafer bonding techniques. As described in Herner et al. filed on even date herewith, metal layer 11 tends to serve as an excellent adhesion layer between wafer 20 and receiver wafer 60, and bonding may be achieved with minimal pressure and/or temperature.

FIG. 7b shows the structure inverted, with receiver wafer 60 at the bottom. Lamina 40 is exfoliated from wafer 20 along cleave plane 30, creating second surface 62. Second surface 62 is optionally roughened, and is cleaned. Intrinsic amorphous silicon layer 76 is deposited on second surface 62, followed by p-doped amorphous silicon layer 78. The thicknesses of intrinsic amorphous layer 76 and p-doped amorphous layer 78 may be about the same as intrinsic amorphous layer 72 and n-doped amorphous layer 74, respectively, or may be different. Next antireflective layer 64, which may be, for example, silicon nitride, is formed on p-type amorphous layer 78 by any suitable method. In alternative embodiments, antireflective layer 64 may be a transparent conductive oxide (TCO). If this layer is a TCO, it may be, for example, of indium tin oxide, tin oxide, titanium oxide, zinc oxide, etc. A TCO will serve as both a top electrode and an antireflective layer and may be between about 500 and 1500 angstroms thick, for example, about 900 angstroms thick.

Finally wiring 57 is formed on antireflective layer 64. Wiring 57 can be formed by any appropriate method. In a preferred embodiment, wiring 57 is formed by screen printing.

FIG. 7b shows completed photovoltaic assembly 82, which includes lamina 40 and receiver element 60. Photovoltaic assembly 82 comprises a photovoltaic cell. In this embodiment, lamina 40 is the base, or a portion of the base, of the photovoltaic cell. Heavily doped p-type amorphous layer 78 is the emitter, or a portion of the emitter. Amorphous layer 76 is intrinsic, but in practice, amorphous silicon will include defects that cause it to behave as if slightly n-type or slightly p-type. If it behaves as if slightly p-type, then, amorphous layer 76 will function as part of the emitter, while if it behaves as if slightly n-type, it will function as part of the base.

As in prior embodiments, a plurality of such photovoltaic assemblies 82 will be fabricated, and each will be inspected for defects and tested for performance and sorted. Photovoltaic assemblies will be selected to be affixed to a substrate 90, electrically connected in series, and fabricated into a completed photovoltaic module. In alternative embodiments, photovoltaic assemblies 82 could be affixed to a transparent superstrate (not shown).

### Example

### Exfoliated Surface as Back Surface

In the embodiments so far described, the cell was fabricated such that the first surface of the lamina, the original surface of the donor body, is the back surface of the finished cell, and the second surface created by exfoliation is the front surface, where light enters the cell. An embodiment will be described in which the lamina is exfoliated to a transparent receiver element where light travels through the receiver element. In this embodiment, the original surface of the donor body, affixed to the receiver element, is the front surface where light enters the cell, while the second surface, created by exfoliation, is the back surface of the finished cell.

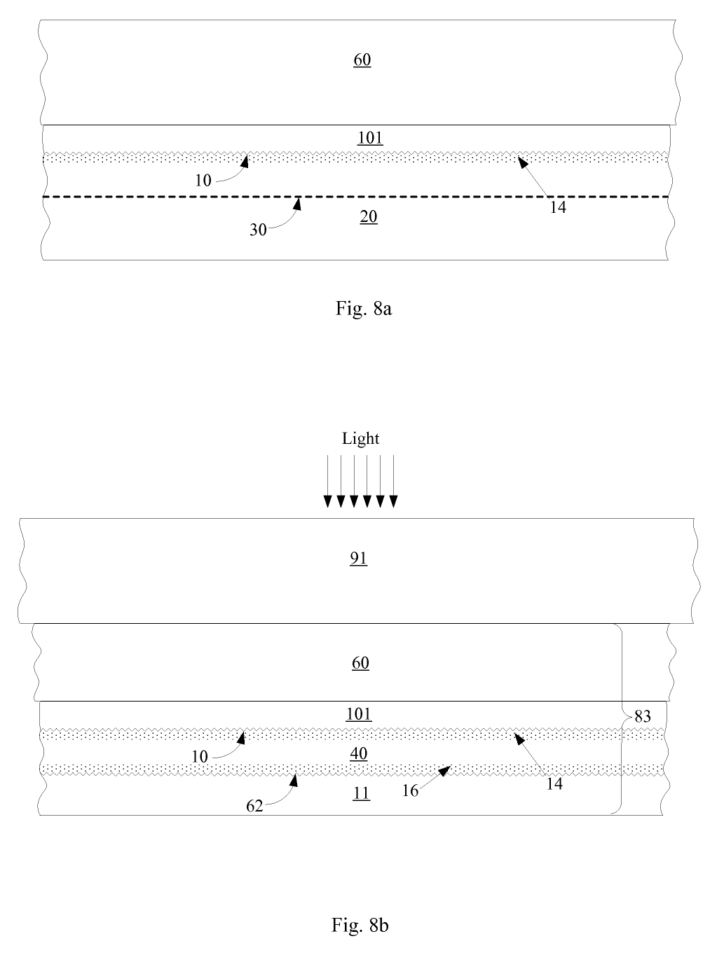

Turning to FIG. 8a, in this example semiconductor donor body 20 is a lightly p-doped silicon wafer. First surface 10 of wafer 20 is optionally textured as in prior embodiments. Next a doping step, for example by diffusion doping, forms n-doped region 14. If oxygen is present during this doping step, a thin oxide (not shown) will grow at first surface 10. It will be understood that, as in all embodiments, conductivity types can be reversed. Gas ions are implanted through first surface 10 to define cleave plane 30.

First surface 10 is cleaned, removing any oxide formed during diffusion doping. In the present example, TCO 101 is between first surface 10 and receiver element 60. This TCO 101 is indium tin oxide, titanium oxide, zinc oxide, or any other appropriate material, and can be deposited on first surface 10, on receiver element 60, or both. As TCO 101 serves as both a contact and as an antireflective coating, its thickness should be between about 500 and about 1500 angstroms thick, for example about 900 angstroms thick. Wafer 20 is affixed to receiver element or wafer 60 at first surface 10, and wafer 20 and receiver wafer 60 are bonded, for example using conventional wafer bonding techniques. The TCO layer 101 may serve as a highly effective adhesion layer, aiding bonding. Note receiver wafer 60 is a transparent material such as borosilicate glass.

Turning to FIG. 8b, lamina 40 is exfoliated from wafer 20 at cleave plane 30, creating second surface 62. Second surface 62 is optionally textured. Conductive layer 11 is deposited on second surface 62. Conductive layer 11 is preferably a metal, for example aluminum. If conductive layer 11 is aluminum, an anneal forms p-doped layer 16. If some other material is used for conductive layer 11, p-doped layer 16 must be formed by a diffusion doping step before conductive layer 11 is formed. Aluminum layer 11 can be formed by many methods, for example by sputtering. Note that in this embodiment, a conductive layer, TCO 101, intervenes between lamina 40 and receiver wafer 60.

As in prior embodiments, photovoltaic assemblies are fabricated, then each is inspected and tested. A photovoltaic module is formed by affixing a plurality of photovoltaic assemblies to a superstrate 91. FIG. 8b shows the completed photovoltaic assembly 83 affixed to superstrate 91 in a completed photovoltaic module. Incident light falls on superstrate 91, and is transmitted through superstrate 91, receiver wafer 60, and TCO 101 before entering the photovoltaic cell at second surface 62. Lamina 40 comprises both the base and emitter of the photovoltaic cell. In an alternative embodiment, photovoltaic assemblies 83 can be affixed to a substrate instead.

In any of the embodiments so far described, after cleaving a first lamina from the semiconductor donor body, the semiconductor donor body can be again subjected to processing, implanted with one or more species of gas ions, affixed to a receiver or receiver element, and another semiconductor lamina cleaved from the semiconductor donor body. This semiconductor lamina can be used to form another photovoltaic assembly, as described, or can be used for some other purpose. The process can be performed additional times, with multiple laminae cleaved from the semiconductor donor body. After cleaving one or more semiconductor lamina from the original semiconductor donor body, the donor body can be reused for some other purpose, or resold for some other purpose.

A variety of embodiments has been provided for clarity and completeness. Clearly it is impractical to list all embodiments. Other embodiments of the invention will be apparent to one of ordinary skill in the art when informed by the present specification.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for forming a photovoltaic assembly, the method comprising:
affixing a semiconductor donor body at a first surface to a receiver element, the semiconductor donor body having a donor widest dimension and the receiver element having a receiver widest dimension, wherein the receiver widest dimension does not exceed the donor widest dimension by more than 50 percent;
cleaving a semiconductor lamina from the semiconductor donor body along a cleave plane, wherein the semiconductor lamina remains affixed to the receiver element; and
completing fabrication of the photovoltaic assembly, wherein the completed photovoltaic assembly comprises the semiconductor lamina and the receiver element, and wherein the semiconductor lamina comprises a portion of a base or emitter of a photovoltaic cell.

2. The method of claim 1 wherein the semiconductor lamina has a thickness between about 1 and about 20 microns.

3. The method of claim 2 wherein the receiver element comprises a metal or metal compound, glass, or plastic.

4. The method of claim 1 further comprising, before the affixing step, implanting one or more species of gas ions through the first surface of the donor body to define the cleave plane.

5. The method of claim 1 further comprising affixing the photovoltaic assembly to a substrate or superstrate, wherein a plurality of other photovoltaic assemblies is affixed to the same substrate or superstrate.

6. The method of claim 1 wherein the semiconductor lamina comprises the photovoltaic cell.

7. A method for forming a photovoltaic module, the method comprising:
forming a plurality of photovoltaic assemblies, each photovoltaic assembly comprising a semiconductor lamina and a receiver element, wherein each semiconductor lamina has a thickness between about 0.2 and about 50 microns, each semiconductor lamina is bonded to one of the receiver elements, each receiver element has a thickness of at least 80 microns, and each semiconductor lamina comprises at least a portion of a base or emitter of a photovoltaic cell;
testing each photovoltaic assembly of the plurality;
selecting a subset of the plurality for inclusion in the photovoltaic module based on results of the testing step; and
affixing at least some of the plurality of photovoltaic assemblies to a substrate or superstrate to form the photovoltaic module.

8. The method of claim 7 wherein the thickness of each semiconductor lamina is between about 1 and about 10 microns.

9. The method of claim 7 wherein the receiver elements comprise metal or a metal compound, glass, or plastic.

10. The method of claim 7 wherein the step of forming a plurality of photovoltaic assemblies comprises:
affixing each one of a plurality of semiconductor donor wafers to one of the receiver elements; and
cleaving one of the semiconductor laminae from each one of the semiconductor donor wafers along a cleave plane.

11. The method of claim 10 wherein the step of forming a plurality of photovoltaic assemblies further comprises, before the step of affixing each of a plurality of semiconductor donor wafers to one of a plurality of receiver elements, implanting one or more species of gas ions into each semiconductor donor wafer to define the cleave plane.

12. The method of claim 7 wherein the testing step comprises testing the photovoltaic cells for conversion efficiency, and wherein the method further comprises grouping the photovoltaic cells by conversion efficiency.

13. A photovoltaic assembly comprising:
a semiconductor lamina, the semiconductor lamina having a thickness between about 1 and about 50 microns and having a lamina widest dimension; and
a receiver element having a receiver widest dimension, wherein the receiver widest dimension does not exceed the lamina widest dimension by more than about 50 percent, wherein the receiver is bonded to the semiconductor lamina.

14. The photovoltaic assembly of claim 13 wherein the semiconductor lamina comprises substantially crystalline silicon.

15. The photovoltaic assembly of claim 13 wherein the semiconductor lamina comprises at least a portion of a base of a photovoltaic cell.

16. The photovoltaic assembly of claim 13 wherein the receiver element comprises metal or a metal compound, glass, or plastic.

17. The photovoltaic assembly of claim 13 wherein a conductive layer intervenes between the semiconductor lamina and the receiver element.

18. A first photovoltaic assembly comprising:
a first photovoltaic cell;
a semiconductor lamina having a thickness between about 1 and about 20 microns, the semiconductor lamina comprising at least a portion of a base of the first photovoltaic cell, the semiconductor lamina having a lamina widest dimension; and
a receiver element having a receiver widest dimension, wherein the receiver widest dimension does not exceed the lamina widest dimension by more than about 50 percent, wherein the receiver is bonded to the semiconductor lamina.

19. The first photovoltaic assembly of claim 18 wherein the semiconductor lamina comprises substantially crystalline silicon.

20. The first photovoltaic assembly of claim 18 wherein:
the first photovoltaic assembly is affixed to a superstrate or substrate of a photovoltaic module,
wherein a second photovoltaic assembly comprising a second photovoltaic cell is affixed to the superstrate or substrate, and
wherein the first photovoltaic cell of the first photovoltaic module is electrically in series with the second photovoltaic cell.

21. The first photovoltaic assembly of claim 18 further comprising a conductive layer between the semiconductor lamina and the receiver element.

22. A photovoltaic module comprising:
i) a plurality of photovoltaic assemblies, each photovoltaic assembly comprising:
a) a semiconductor lamina having a thickness between about 0.2 and about 50 microns, the semiconductor lamina comprising at least the base of a photovoltaic cell,
b) a receiver element at least about 80 microns thick, the semiconductor lamina bonded to the receiver element, and
c) the photovoltaic cell; and
ii) a substrate or superstrate, each of the photovoltaic assemblies affixed to the substrate or superstrate, wherein the photovoltaic cell of one photovoltaic assembly is electrically connected in series to the photovoltaic cell of at least one other photovoltaic assembly.

23. The photovoltaic module of claim 22 wherein the receiver element of each photovoltaic assembly comprises metal or a metal compound, glass, or plastic.

24. The photovoltaic module of claim 22 wherein each of the semiconductor laminae of the plurality of photovoltaic assemblies comprises substantially crystalline silicon.

25. The photovoltaic module of claim 22 wherein each photovoltaic assembly further comprises a conductive layer between the semiconductor lamina and the receiver element.
